(19) United States
(12) Patent Application Publication
(10) Pub. No.: US 2013/0038353 A1
(43) Pub. Date: Feb. 14, 2013

(54) SYSTEM AND METHOD FOR SIMULATING BIOFIDELIC SIGNALS

(71) Applicants: Sliman Bensmaia, Baltimore, MD (US); R. Jacob Vogelstein, Bethesda, MD (US); Ralph Etienne-Cummings, Washington, DC (US); Alexander F. Russell, (US); Sung Soo Kim, Perry Hall, MD (US); Arun P. Sripati, Pittsburgh, PA (US)

(72) Inventors: Sliman Bensmaia, Baltimore, MD (US); R. Jacob Vogelstein, Bethesda, MD (US); Ralph Etienne-Cummings, Washington, DC (US); Alexander F. Russell, (US); Sung Soo Kim, Perry Hall, MD (US); Arun P. Sripati, Pittsburgh, PA (US)

(73) Assignee: THE JOHNS HOPKINS UNIVERSITY, Baltimore, MD (US)

(21) Appl. No.: 13/541,791

(22) Filed: Jul. 5, 2012

Related U.S. Application Data
(60) Provisional application No. 61/504,856, filed on Jul. 6, 2011.

(51) Int. Cl. G01R 23/165

(52) U.S. Cl. 327/44

(57) ABSTRACT

A system for simulating biofidelic signals includes a transducer and a neural transmitter port. The transducer is affected by a parameter and provides an alternating electrical signal based on an effect of the parameter. The neural transmitter port receives a processed electrical signal and outputs the processed electrical to a neural transmitter. The system further includes an input portion, a band-pass filter, and an integrate-and-fire mechanism. The input portion outputs a first signal based on the alternating electrical signal. The band-pass filter outputs a first filtered signal based on the first signal. The integrate-and-fire mechanism generates the processed electrical signal based on the first filtered signal.

### CROSS-REFERENCE TO RELATED APPLICATIONS

The present application claims priority to and the benefit of prior-filed and co-pending U.S. Provisional Application No. 61/504,856, filed Jul. 6, 2011, the entire disclosure of which is hereby incorporated herein by reference.

### STATEMENT OF GOVERNMENTAL INTEREST

This invention was made with government support under contract number N66001-06-C-8005 awarded by the Defense Advanced Research Projects Agency (DARPA). The government has certain rights in the invention.

### BACKGROUND OF THE INVENTION

1. Field of the Invention

Example embodiments of the present invention generally relate to prostheses and, more particularly, relate to sensorized neural prostheses.

2. Description of the Related Art

Neural prostheses are medical devices designed to restore damaged or lost neural functions. Neural prostheses typically involve sensing the environment using artificial sensors, converting data from these sensors into neural signals and applying electrical stimulation to a neural epithelium to mimic the signals that would have been produced by the sensory environment if the native sensory transducers were still in place.

In touch, the hand is the principal sensory organ and feedback from the hand is critical in the dexterous manipulation of objections. The skin of the hand is innervated by different types of mechanoreceptors. Each mechanoreceptor type conveys different information about the object or surface that is palpated and is sensitive to different aspects of skin deformation.

Slowly adapting type 1 (SA1) mechanoreceptive afferents, that innervate Merkel mechanoreceptors, are sensitive to coarse spatial structure, rapidly adapting (RA) afferents, that innervate Meissner mechanoreceptors, to motion, and Pacinian (PC) afferents, associated with Pacinian mechanoreceptors, to surface microgeometry. When these mechanoreceptors and their associated afferents are stimulated, they produce neural signals to give a person tactile sensory feedback.

FIG. 1 illustrates a conventional neural prosthetic limb 102 for forearm amputees.

As illustrated in FIG. 1, conventional neural prosthetic arm 102 is a prosthetic device designed onto a human arm 104. Since prosthetic arms are well known, a detailed description of conventional neural prosthetic arm 102 is omitted in the interest of brevity.

Conventional neural prosthetic arm 102 includes: a plurality of digits, a sample of which is indicated as digit 106; a plurality of transducers, a sample of which is indicated as a transducer 108; a processor 110, neural transmitter port 110 and a neural transmitter 112.

Transducer 108 may typically be embedded in, or disposed on, digit 106 of conventional neural prosthetic arm 102 and is arranged to provide sensory feedbacks indicative of detected stimuli. Processor 110 is embedded in conventional neural prosthetic arm 102. Processor 110 is connected to transducer 108 electrically and is arranged to process received signals from transducer 108. Processor 110 is additionally arranged to transmit the processed received signals to neural transmitter port 112. Neural transmitter port 112 is arranged to provide neural feedback to human arm 104 via neural transmitter 114.

Transducer 108 may be sensors that output electrical signals indicative of changing conditions, non-limiting examples of which include pressure or temperature sensors. Processor 110 may be any devices that convert feedbacks from transducer 108 to signals that may be interpreted by the human nervous system. Neural transmitter port 112 may be any devices that interface with neural transmitter 114 to forward neural signals to neural transmitter 114.

In operation, when transducer 108 detects a stimulus, such as an application of pressure to digit 106, transducer 108 transmits a signal 116 indicative of the sensed change of pressure to processor 110 via electrical connection. Processor 110 translates signal 116 to a neural signal 118, non-limiting examples of which include a pattern of afferent activity that may be interpreted by the nervous system. Processor 110 transmits neural signal 118 to neural transmitter port 110. Neural transmitter port 112 transmits neural signal 118 to neural transmitter 114. Neural transmitter 114 transmits neural signal 118 to a nerve within the wearer's nervous system. As a result, a wearer would detect a change of condition experienced by conventional neural prosthetic arm 102.

A problem associated with conventional neural prosthetic limb 102 is the lack of tactile sensory feedback experienced by the wearer. Although a wearer would receive sensory feedback from conventional neural prosthetic limb 102, the feedback is imprecise and unnatural as neural transmitter port 112 does not elicit a pattern of afferent activity that is equivalent to the sequence expected if the same stimulus were delivered to the natural limb replaced by conventional neural prosthetic limb 102.

What is need is a system for use with a transducer and neural transmitter port to provide tactile sensory feedback to recreate natural sensation in a prosthesis.

### SUMMARY OF THE INVENTION

Example embodiments of the present invention include a system for use with a transducer and neural transmitter port to provide tactile sensory feedback to recreate natural sensation in a prosthesis.

A system is provided for use with a transducer and a neural transmitter port. The transducer can be affected by a parameter and provides an alternating electrical signal based on an effect of the parameter. The neural transmitter port can receive a processed electrical signal and output the processed electrical to a neural transmitter. The system includes an input portion, a band-pass filter, and an integrate-and-fire mechanism. The input portion can output a first signal based on the alternating electrical signal. The band-pass filter can output a first filtered signal based on the first signal. The integrate-and-fire mechanism can generate the processed electrical signal based on the first filtered signal.

Additional advantages and novel features of example embodiments of the invention are set forth in part in the description that follows, and in part will become apparent to those skilled in the art upon examination of the following or may be learned by practice of the invention. The advantages of example embodiments of the invention may be realized and attained by means of the instrumentalities and combinations particularly pointed out in the appended claims.

### BRIEF DESCRIPTION OF THE DRAWINGS

The accompanying drawings, which are incorporated in and form a part of the specification, illustrate exemplary embodiments of the present invention and, together with the description, serve to explain the principles thereof. In the drawings:

FIG. 1 illustrates a conventional neural prosthetic arm with a transducer and a neural transmitter port;

FIG. 2 is a block diagram of a system for use with a transducer and a neural transmitter port in accordance with exemplary embodiments of the present invention;

FIG. 3 is a block diagram of various components of the system of FIG. 2;

FIG. 4 illustrates the rectification index for the SA1, RA and PC afferents;

FIG. 5 illustrates filtering characteristics of band-pass filters of the system in FIG. 2 for the SA1 afferent in the frequency domain;

FIG. 6 illustrates filtering characteristics of band-pass filters of the system in FIG. 2 for the RA afferent in the frequency domain;

FIG. 7 illustrates filtering characteristics of band-pass filters of the system in FIG. 2 for the PC afferent in the frequency domain;

FIG. 8 illustrates the correlation between indentation and retraction filters for the SA1, RA, and PC afferents;

FIG. 9 illustrates mean membrane time constants for the SA1, RA and PC afferents; and

FIG. 10 a waveform of a mean post-spike inhibitory current for the SA1, RA and PC afferents.

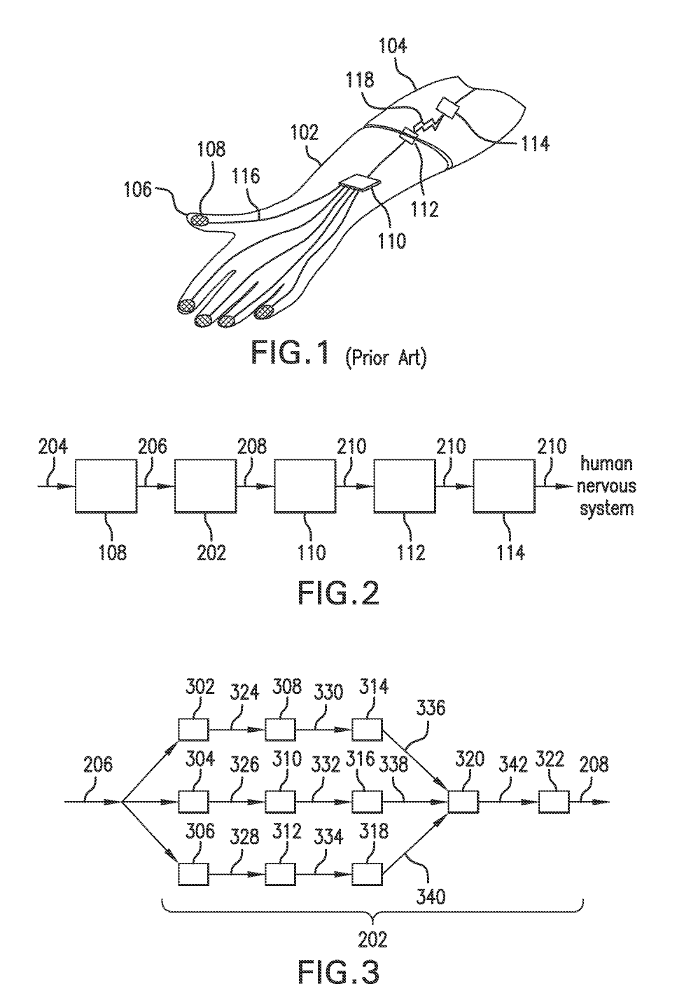

### DETAILED DESCRIPTION

In contrast to the prior art that may have just detected a parameter (e.g. pressure) for the purpose of sensory feedback, example embodiments of the present invention detect the parameter and multiple derivatives of the parameter, such as the first derivative, the second derivative, the third derivative, etc.

In accordance with example embodiments of the present invention, in a non-limiting example embodiment, the parameter may be pressure, the first derivative of pressure may be considered as the rate of change of the pressure (here dubbed velocity), the second derivative may be considered as the change in velocity of the pressure (here dubbed acceleration), and the third derivative may be the change in acceleration of the pressure (here dubbed jerk). These additional aspects are sensed and used by the human body to produce tactile sensory feedback.

Another example embodiment of the present invention deals with a precise type of rectification of a detected signal. For example, with respect to pressure, pressure sensitive sensory receptors in the skin may not only detect pressure (e.g. indentation) and its derivatives, they may also detect negative pressure (e.g. retraction) and its derivatives related to the skin being restored. However, the retraction pressure signals may not be in direct one to one correspondence to the indentation signals. As such, in accordance with this example embodiments of the present invention, a rectification of pressure signals, which includes indentation and retraction, is not a full wave rectification, but it is a partial rectification.

Yet another example embodiment of the present invention prevents flooding a sensory receptor with unneeded signals, gibberish if you will. More specifically, a system in accordance with example embodiments of the present invention filters out a portion of the parameter signals received by a transducer and only passes a band of frequencies that a sensory receptor has evolved to receive. This aspect therefore mimics the sensory receptors in humans. To further explain this notion, consider the following explanation of hearing aids.

With people having a specific type of hearing disability, a damaged or improperly developed inner ear has a decreased ability to sense sound, wherein all frequencies are not sensed at the same amplitude. More specifically, for some people with a damaged or improperly developed inner ear, some frequencies or a band of frequencies, are attenuated as compared with the remaining detected frequencies. If a hearing aid were to simply amplify all frequencies by a constant amount, the resultant amplified signal may amount to gibberish to the person. Accordingly, hearing aids are designed to amplify only the predetermined frequencies that the person cannot perceive accurately. Further, the amount of amplification should counter the amount of attenuation of the frequencies that the person cannot perceive accurately. Example embodiments of the present invention apply this “band specific” aspect to all sensory receptors.

In accordance with another example embodiment of the present invention, a “band specific” signal is generated by filtering a signal from a transducer. The band specific signal is then used for processing before is it provided to a sensory receptor. In an example embodiment, specific parameters associated with predetermined sensory receptors are determined. In a non-limiting example embodiment, pressure, its first derivative, its second derivative and the particular frequencies of these signals associated with human tactile sensory receptors are determined. Transmitting an equally amplified signal across all frequencies into a pressure sensitive sensory receptor would amount to providing useless sensory information to the pressure sensitive sensory receptor. To avoid this, example embodiments of the present invention first filter the signals from the transducers in order to generate a signal that more accurately represents a signal that would have been produced by a human nerve cell.

In accordance with these aspects, example embodiments of the present invention detect a plurality of aspects of a single parameter (e.g. the parameter, the first, second and third derivatives of the parameter), rectifies each of these signals in a predetermined manner, and filters each of these signals in a predetermined manner to more closely emulate a natural human sensory receptor.

Example embodiments of the present invention may be applied to many sensory systems, such as touch, taste, hearing, sight, etc. In the non-limiting example embodiment, a pressure based system is discussed herein.

Example embodiments in accordance with example embodiments of the present invention will now be described with reference to FIGS. 2-10.

FIG. 2 is a block diagram of a system 202 for use with transducer 108 and neural transmitter port 112 in accordance with example embodiments of the present invention. The block diagram includes transducer 108, system 202, processor 110, neural transmitter port 112 and neural transmitter 114.

As illustrated in FIG. 2, system 202 is situated between transducer 108 and processor 110. System 202, transducer 108, processor 110 and neural transmitter port 112 may be embedded in, or disposed on prosthesis. Neural transmitter 114 is embedded in the human body. Transducer 108 is arranged to receive a parameter 204 and in turn to provide an alternating electrical signal 206, which is a parameter signal, to system 202. System 202 is arranged to provide a processed electrical signal 208 to processor 110 based on alternating electrical signal 206. Processor 110 is arranged to process processed electrical signal 208 and transmit a neural signal 210 to the neural transmitter port 112. Neural transmitter port 112 is arranged to transmit neural signal 210 to neural transmitter 114. Neural transmitter 114 in turn transmits neural signal 210 to the human nervous system.

Transducer 108 is connected to system 202 via electrical connection. System 202 is connected to processor 110 via electrical connection. Similarly, processor 110 is connected to neural transmitter port 112, which in turn connects to neural transmitter 114 via electrical connection.

Processor 110 may be any devices that convert sensory feedback signals from transducers to neural signals. Neural transmitter port 112 may be any devices that transmit neural signals to neural transmitter 114.

Neural transmitter 114 may be any devices that transmit neural signals converted from sensory signals to the human nerve system. In a non-limiting example embodiment, neural transmitter 114 may be electrodes implanted in a human arm. Other non-limiting examples of neural transmitter 114 include electrodes implanted in human brain, spinal cord, or on the surface of the skin.

Parameter 204 may be a stimulus; non-limiting examples include mechanical and thermal stimuli.

In operation, transducer 108 is affected by an effect or a change of parameter 204. In a non-limiting example embodiment, parameter 204 may be a time-varying pressure to transducer 108. Upon sensing parameter 204, transducer 108 transmits alternating electrical signal 206 to system 202.

System 202 processes alternating electrical signal 206 and transmits processed alternating electrical signal 208 to processor 110. Processor 110 converts processed alternating electrical signal 208 to neural signal 210, then transmits neural signal 210 to neural transmitter port 112. Neural transmitter port 112 forwards neural signal 210 to the human nervous system via neural transmitter 114.

Unlike conventional neural prosthetic limb 102, a wearer of the prosthesis with system 202 will have tactile sensory feedback that recreates natural sensation as a result of system 202. This will be further described with reference to FIGS. 3-10.

FIG. 3 is a block diagram of various components of system 202 as shown in FIG. 2.

System 202 includes an input portion 302, an input portion 304, an input portion 306, a rectifying portion 308, a rectifying portion 310, a rectifying portion 312, a band-pass filter 314, a band-pass filter 316, a band-pass filter 318, a summing portion 320 and an integrate-and-fire (IF) mechanism 322. In this example each of input portion 302, input portion 304, input portion 306, rectifying portion 308, rectifying portion 310, rectifying portion 312, band-pass filter 314, band-pass filter 316, band-pass filter 318, summing portion 320 and integrate-and-fire (IF) mechanism 322 are distinct elements. However, in some embodiments at least two of input portion 302, input portion 304, input portion 306, rectifying portion 308, rectifying portion 310, rectifying portion 312, band-pass filter 314, band-pass filter 316, band-pass filter 318, summing portion 320 and integrate-and-fire (IF) mechanism 322 may be combined as a unitary device. In this example embodiment, input portion 302, input portion 304 and input portion 306 receive signals corresponding to pressure, and its two derivatives, respectively. To be accurate, it should be noted that each input signal is split into positive and negative components for rectifying portion 308, rectifying portion 310 and rectifying portion 312, respectively, each of which has its own filter. However, for purposes of simplifying the discussion, only a single signal is shown for each of rectifying portion 308, rectifying portion 310 and rectifying portion 312.

Input portion 302, input portion 304 and input portion 306 are arranged to provide a signal 324, a signal 326 and a signal 328 to rectifying portion 308, rectifying portion 310 and rectifying portion 312, respectively, based on alternating electrical signal 206.

Rectifying portion 308, rectifying portion 310 and rectifying portion 312 are arranged to provide a rectified signal 330, a recertified signal 332 and a rectified signal 334 to band-pass filter 314, band-pass filter 316 and band-pass filter 318, respectively.

Band-pass filter 314, band-pass filter 316 and band-pass filter 318 are arranged to provide a filtered signal 336, a filtered signal 338 and a filtered signal 340, respectively, to summing portion 320. Summing portion 320 is arranged to provide a summation signal 342 to IF mechanism 322. IF mechanism 322 is arranged to provide processed electrical signal 208 to processor 110 (not shown in the figure).

In a non-limiting example embodiment, alternating electrical signal 206 may be a time-varying pressure stimulus. Input portion 302 may represent pressure, input portion 304 may be a first derivative of alternating electrical signal 206 that represents velocity, input portion 306 may be a second derivative of alternating electrical signal 206 that represents acceleration.

Rectifying portion 308, rectifying portion 310 and rectifying portion 312 may be rectifying mechanism implemented in software or hardware that allow for rectification of signal 324, signal 326 and signal 328, respectively. Non-limiting examples of which include half-wave rectification, partial rectification, full-wave rectification. In this example embodiment, each of rectifying portion 308, rectifying portion 310 and rectifying portion 312 may split its respective signal into positive and negative pressure, and these split signals may then be rectified using a linear operation.

Summing portion 320 sums different signals. IF mechanism 322 approximates the membrane potential dynamics preceding a spike.

As shown in FIG. 3, system 202 is shown to include a separate input portion, rectifying portion and a band-pass filter for each aspect of alternating electrical signal 206. Other embodiments may account for many different possible aspects of a signal. For example, in another non-limiting example embodiment, system 202 may include a fourth input portion (not shown in the figure) that may be a third derivative of alternating electrical signal 206 with additional separate rectifying portion and band-pass filter.

Alternating electrical signal 206 is fed into and processed by system 202.

Input portion 302, rectifying portion 308 and band-pass filter 314 deal with the parameter signal, which may be pressure. Input portion 304, rectifying portion 310 and band-pass filter 316 deal with the first derivative of pressure, which may be velocity. Input portion 306, rectifying portion 312 and band-pass filter 318 deal with the second derivative of pressure, which may be acceleration.

The resulting filtered signal 336, filtered signal 338 and filtered signal 340 are fed into summing portion 320. Summing portion 320 adds filtered signal 336, filtered signal 338 and filtered signal 340 together to create summation signal 342. Summation signal 342 is fed to IF mechanism 322 to create processed electrical signal 208. IF mechanism 322 approximates the membrane potential dynamics preceding a spike.

A brain is able to interpret pressure and its derivatives differently. However, the brain needs to receive those signals correctly. Example embodiments of the present invention are able to take that into account.

Accordingly, rectifying portion 308 is able to rectify pressure in the appropriate amount. The rectification is a partial rectification between full wave rectification and half wave rectification, because the brain also has to detect the retraction.

Similarly, rectifying portion 310 is able to rectify the first derivative of pressure differently than rectifying portion 308 as the brain may deal with the first derivative of pressure differently than pressure.

Rectifying portion 312 is able to rectify the second derivative of pressure differently than rectifying portion 308 and rectifying portion 310.

Furthermore, as the human sensory receptors may not be able to detect fast moving pressure, band-pass filter 314 only passes pressure in a specific frequency range and filters out information that may be interpreted as gibberish by the central nervous system.

Similarly, band-pass filter 316 has a filtering characteristic associated with the first derivative of pressure and band-pass filter 318 has a filtering characteristic associated with the second derivative of pressure.

Therefore, in example embodiments of the present invention is the recognition that the human brain processes sensory signals based on a parameter, its first derivative, its second derivative, etc. and in accordance with the signals provided by the natural sensory receptors. However, to emulate these natural sensory receptors, a parameter and its derivatives are processed in a particular manner.

For purposes of discussion, presume that transducer 108 is a pressure sensor. In operation, transducer 108 (not shown in this figure) transmits alternating electrical signal 206 to system 202 as a result of sensing an effect of parameter 204 (not shown in this figure), which in this case is pressure. Alternating electrical signal 206 is fed to input portion 302, input portion 304 and input portion 306 for processing.

Input portion 302 creates signal 324 by smoothing the alternating electrical signal 206 to reduce noise. Any known smoothing method may be used. In a non-limiting example embodiment, a 20 kHz sampling rate is used. Input portion 302 then re-samples signal 324. In a non-limiting example embodiment, signal 324 is re-sampled to 1 kHz for the SA1 and RA afferents and 4 kHz for the PC afferent. Then input portion 302 outputs signal 324 to rectifying portion 308.

Input portion 304 creates signal 326 by smoothing the alternating electrical signal 206 and then taking the first derivative of alternating electrical signal 206.

Input portion 304 re-samples signal 326 and then transmits signal 326 to rectifying portion 310. In a non-limiting example embodiment, 1 kHz re-sampling rate is used for the SA1 and RA afferents and 4 kHz for the PC afferent.

Input portion 306 creates signal 328 by first smoothing the alternating electrical signal 206 and then taking the second derivative of alternating electrical signal 206. In a non-limiting example embodiment, a 20 kHz sampling rate is used for smoothing.

Input portion 306 re-samples signal 328 and then transmits signal 326 to rectifying portion 312. In a non-limiting example embodiment, 1 kHz re-sampling rate is used for the SA1 and RA afferents and 4 kHz for the PC afferent.

Rectifying portion 308 separates signal 324 into its positive and negative components (i.e., indentations and retractions in the case of pressure) and rectifies the positive and negative components. This partitioning allows for full-wave, half-wave, or partial rectification of incoming signals to rectifying portion 308 using appropriate linear transformations. Rectifying portion 308 performs rectification based on a rectification index.

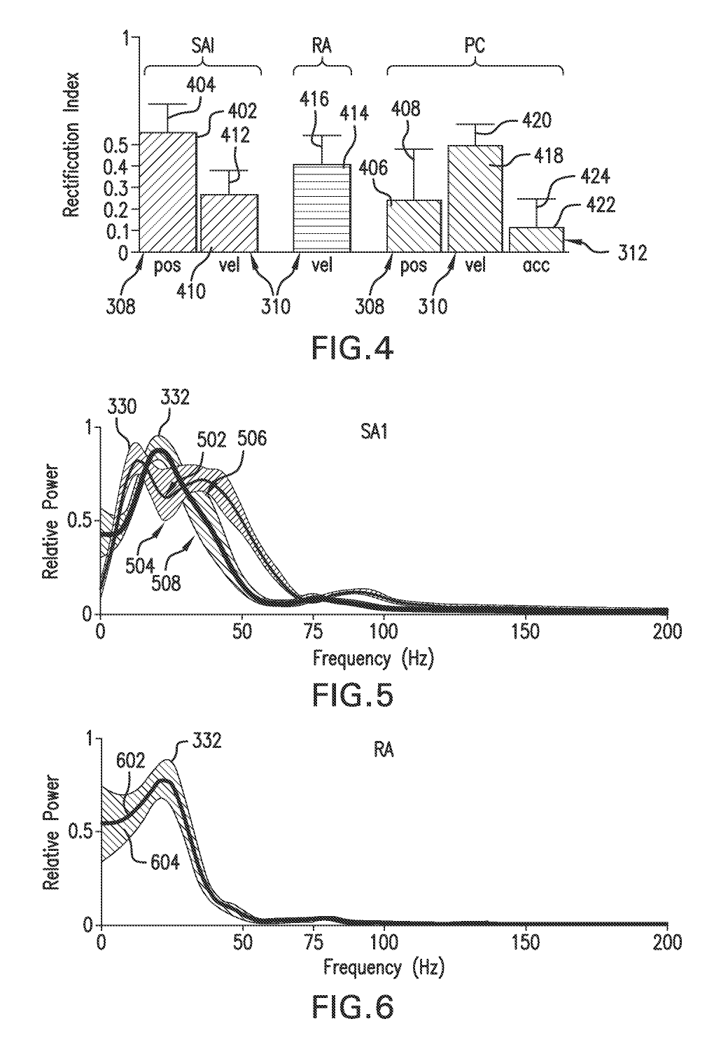

In a non-limiting example embodiment, the rectification index is less than or equal to 1. Rectification index is given by:

$$rectification index = 1 - \frac{4}{π} {tan}^{- 1} ( \frac{{\sum }_{t} \vert {H}_{i} ( t ) - {H}_{r} ( t ) \vert}{{\sum }_{t} \vert {H}_{i} ( t ) + {H}_{r} ( t ) \vert} ) \qquad ( 1 )$$

where Hᵢ(f) and Hᵣ(f) are the indentation and retraction filters. A rectification index of −1 indicates no rectification; 0 half-wave rectification; 1 full-wave rectification. Afferents tended to exhibit rectification properties intermediate between half- and full-wave. This will be further described with reference to FIG. 4.

FIG. 4 illustrates the rectification index for SA1, RA and PC mechanoreceptors.

This figure includes examples of rectifying portion 308, rectifying portion 310 and rectifying portion 312.

Rectifying portion 308 includes SA1 position rectification portion 402, the variability in SA1 position rectification across the population 404, PC position rectification portion 406 and variability in PC position rectification 408.

Rectifying portion 310 includes SA1 velocity rectification portion 410, SA1 velocity rectification variability 412, RA velocity rectification portion 414, RA velocity rectification variability 416, PC velocity rectification portion 418 and PC velocity rectification variability 420.

Rectifying portion 312 includes PC acceleration rectification portion 422 and PC acceleration rectification variability 424.

SA1 position rectification portion 402 and SA1 velocity portion 410 may be rectification index values for the SA1 afferent. SA1 position rectification variability 404 and SA1 velocity rectification variability 412 may be an acceptable amount of error associated with SA1 position rectification portion 402 and SA1 velocity portion 810 respectively.

RA velocity rectification portion 414 may be a rectification index value for the RA afferent. RA velocity rectification variability 416 may be an acceptable amount of error associated with RA velocity rectification portion 414.

PC position rectification portion 406, PC velocity rectification portion 418 and PC acceleration rectification portion 422 may be rectification index values for the PC afferent. PC position rectification variability 408, PC velocity rectification variability 420 and PC acceleration rectification variability 424 may be an acceptable amount of error associated with PC position rectification portion 406, PC velocity rectification portion 418 and PC acceleration rectification portion 422 respectively.

As illustrated in the figure, SA1 position rectification portion 402 has a value of about 0.55-0.6, SA1 velocity rectification portion 410 has a value of 0.3; RA velocity rectification portion 414 has a value of 0.4; PC position rectification portion 806 has a value of about 0.3, PC velocity rectification portion 818 has a value of 0.5 and PC acceleration rectification portion 422 has a value of 0.1.

As all the rectification index values are between 0 and 1, this indicates that rectifying portion 308, rectifying portion 310 and rectifying portion 312 apply partial rectification for the SA1, RA and PC afferents. Further, it should be noted that rectification index values as applied by each rectifying portion do not have to be equal. In this example, rectification index values as applied by each of rectifying portion 308, rectifying portion 310 and rectifying portion 312 are not equal.

Returning to FIG. 3, rectifying portion 308 transmits the appropriate rectified component as rectified signal 330 to band-pass filter 314. In a non-limiting example embodiment, the negative component of signal 324 is multiplied by a negative rectification index, thus making the negative component of signal 324 positive, and the positive component of signal 324 is unmodified. The combination of the modified negative component of signal 324 (now a positive component) and the positive component of signal 324 is transmitted as rectified signal 330 to band-pass filter 314.

Rectifying portion 310 and rectifying portion 312 performs a similar processing for signal 326 and signal 328, respectively. Additionally, rectifying portion 310 and rectifying portion 312 perform rectification based on the rectification index. In a non-limiting example embodiment, the rectification index is less than or equal to 1.

Rectifying portion 310 and rectifying portion 312 then transmit rectified signal 332 and rectified signal 334 to band-filter 316 and band-filter 318 respectively.

Band-pass filter 314, band-pass filter 316 and band-pass filter 318 filter rectified signal 330, rectified signal 332 and rectified signal 334 to specific frequency ranges suitable for the SA1, RA and PC mechanoreceptive afferents. In a non-limiting example embodiment, a finite impulse response filter is used. This will be further described with reference to FIGS. 5-7.

FIG. 5 illustrates filtering characteristics of band-pass filter 314 and band-pass filter 316 for the SA1 mechanoreceptor in the frequency domain.

The figure includes examples of rectified signal 330 and rectified signal 332.

Rectified signal 330 includes signal portion 502 and variability band 504. Rectified signal 332 includes signal portion 506 and variability band 508.

Signal portion 502 may be frequency domain representation of rectified signal 330. Variability band 504 may be an acceptable amount of error associated with signal portion 402 occurred during transformation or approximation.

Signal portion 506 may be frequency domain representation of rectified signal 332. Variability band 508 may be an acceptable amount of error associated with signal portion 406 occurred during transformation or approximation.

As the SA1 afferent is naturally sensitive to the position and velocity of skin movements (e.g. an object pushing into a finger), thus band-pass filter 314 and band-pass filter 316 filter rectified signal 330 and rectified signal 332 respectively to mimic the natural response of the SA1 afferent.

Band-pass filter 314 exhibits low-pass filtering characteristic as signal portion 502 passes through from 0 Hz to about 75. After 75 Hz, signal portion 502 is cut off.

Band-pass 316 similarly exhibits low-pass filtering characteristic as signal portion 506 passes through from 0 Hz to about 75 Hz. After 100 Hz, signal portion 506 is cut off.

FIG. 6 illustrates filtering characteristics of band-pass filter 316 for the RA afferent in the frequency domain.

This figure includes an example of rectified signal 332.

Rectified signal 332 includes signal portion 602 and variability band 604.

Signal portion 602 may be frequency domain representation of rectified signal 332. Variability band 604 may be an acceptable amount of error associated with signal portion 602 occurred during transformation or approximation.

As the RA mechanoreceptor is naturally sensitive to the velocity of skin movements, band-pass filter 316 filters rectified signal 332 to mimic the natural response of the RA afferent.

Band-pass 316 similarly exhibits low-pass filtering characteristic as signal portion 602 passes through from 0 Hz to about 50 Hz. After 50 Hz, signal portion 602 is cut off.

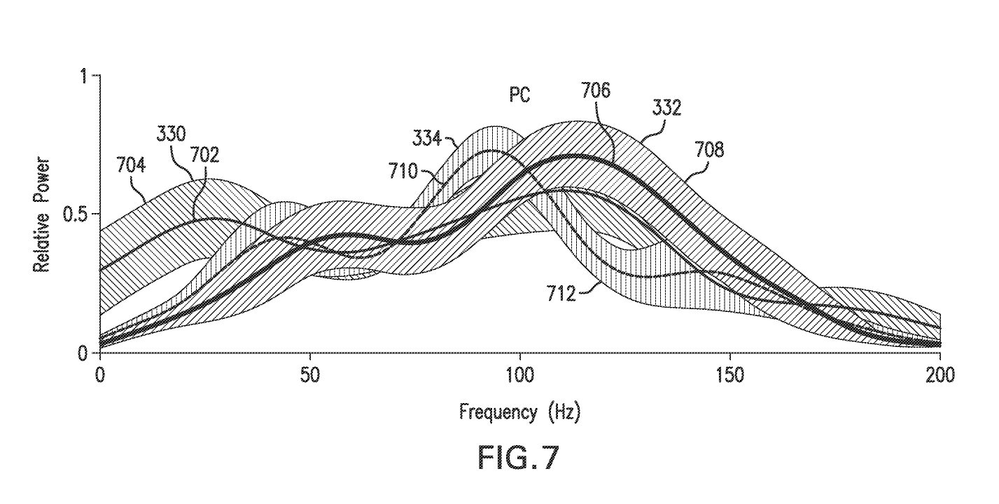

FIG. 7 illustrates filtering characteristics of band-pass filter 314, band-pass filter 316 and band-pass filter 318 for the PC afferent in the frequency domain.

This figure includes examples of rectified signal 330, rectified signal 332 and rectified signal 334.

Rectified signal 330 includes signal portion 702 and variability portion 704. Rectified signal 332 includes signal portion 706 and variability portion 708. Rectified signal 334 includes signal portion 710 and variability portion 712.

Signal portions 702, 706, 710 may be frequency domain representations of rectified signal 330, rectified signal 332 and rectified signal 334, respectively. Variability portions 704, 708, 712 may be acceptable amounts of error associated with signal portions 702, 706, 710 occurred during transformation or approximation, respectively.

As the PC afferent is naturally sensitive to the position, velocity and acceleration of skin movements, band-pass filter 314, band-pass filter 316 and band-pass filter 318 filter rectified 330, rectified signal 332 and rectified signal 334, respectively, to mimic the natural response of the PC afferent.

Band-pass filter 314, band-pass filter 316 and band-pass filter 318 all exhibit band-pass filtering characteristics as signal portions 702, 704 and 708 are not filtered from 0 Hz to 200 Hz. After 200 Hz, signal portions 702, 704 and 708 are cut off.

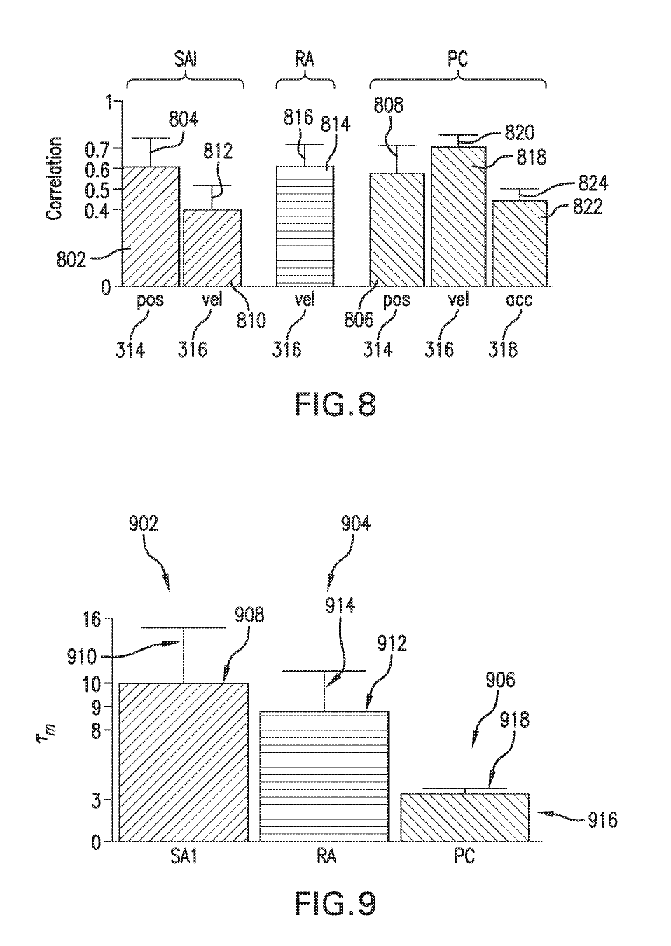

As rectified signal 330, rectified signal 332 and rectified signal 334 may have just positive, or just negative, or both positive and negative components of signal 324, signal 326 and signal 328, band-pass filter 314, band-pass filter 316 and band-pass filter 318 may be used to filter either or both the positive and the negative components. This will be further described with reference to FIG. 8 below.

FIG. 8 illustrates the correlation between band-pass filter 314, band-pass filter 316 and band-pass filter 318 and the positive and negative components of rectified signal 330, rectified signal 332 and rectified signal 334 for the SA1, RA and PC afferents.

First band-pass filter 314 includes SA1 position correlation portion 802, SA1 position correlation varability 804, PC position correlation portion 806, PC position correlation variability 808. Band-pass filter 316 includes SA1 velocity correlation portion 810, SA1 velocity correlation variability 812, RA velocity correlation portion 814, RA velocity correlation variability 816, PC velocity correlation portion 818, PC velocity correlation variability 820.

SA1 position correlation portion 802 may be correlation value between band-pass filter 314 filtering rectified signal 330 containing just positive component of signal 324 and rectified signal 330 containing just negative component of signal 324 for the SA1 afferent. SA1 position correlation variability 804 may be an acceptable amount of error associated with SA1 position correlation portion 802.

PC position correlation portion 806 may be correlation value between band-pass filter 314 filtering rectified signal 330 containing just positive component of signal 324 and rectified signal 330 containing just negative component of signal 324 for the PC afferent. PC position correlation variability 808 may be an acceptable amount of error associated with PC position correlation portion 806.

SA1 velocity correlation portion 810 may be correlation value between band-pass filter 316 filtering rectified signal 332 containing just positive component of signal 326 and rectified signal 332 containing just negative component of signal 326 for the SA1 afferent. SA1 velocity correlation variability 812 may be an acceptable amount of error associated with SA1 velocity correlation portion 810.

RA velocity correlation portion 814 may be correlation value between band-pass filter 316 filtering rectified signal 332 containing just positive component of signal 326 and rectified signal 332 containing just negative component of signal 326 for the RA afferent. RA velocity correlation variability 816 may be an acceptable amount of error associated with RA velocity correlation portion 814.

PC velocity correlation portion 818 may be correlation value between band-pass filter 316 filtering rectified signal 332 containing just positive component of signal 326 and rectified signal 332 containing just negative component of signal 326 for the PC afferent. PC velocity correlation error 820 may be an acceptable amount of error associated with PC velocity correlation portion 818.

PC acceleration correlation portion 822 may be correlation value between band-pass filter 318 filtering rectified signal 334 containing just positive component of signal 328 and rectified signal 334 containing just negative component of signal 328 for the PC afferent. PC acceleration correlation variability 822 may be an acceptable amount of error associated with PC acceleration correlation portion 820.

As illustrated in FIG. 8, SA1 position correlation portion 802 has a correlation value of 0.6, SA1 velocity correlation portion 810 has a correlation value of 0.4; RA velocity correlation portion 814 has a value of 0.6; PC position correlation portion 806 has a value of 0.6, PC velocity correlation portion 818 has a value of 0.7, PC acceleration correlation portion 822 has a value of 0.4. Overall, FIG. 8 indicates that band-pass filter 314, band-pass filter 316 and band-pass filter 318 tend to be correlated for the SA1, RA and PC afferents.

Additionally, band-pass filter 314, band-pass filter 316 and band-pass filter 318 may be used as the indentation and retraction filters for calculating the input to the IF.

Returning to FIG. 3, band-pass filter 314, band-pass filter 316 and band-pass filter 318 then transmit the filtered rectified signal 330, rectified signal 332 and rectified signal 334 as filtered signal 336, filtered signal 338 and filtered signal 340, respectively, to summing portion 320.

Summing portion 320 performs a summing operation on filtered signal 336, filtered signal 338 and filtered signal 340 to create summation signal 342. Summing portion 320 then transmits summation signal 342 to IF mechanism 322 for further processing.

IF mechanism 322 processes summation signal 342 to create processed electrical signal 208 that is equivalent to a neural signal generated by a natural limb affected by the same effect of the same stimulus, namely parameter 204. IF mechanism 322 then transmits electrical signal 208 to processor 110.

To create a signal that is equivalent to a neural signal generated by a natural limb affected by the same effect of the same stimulus, IF mechanism 322 has to generate a train of spikes that is equivalent to a train of spikes generated by the SA1, or RA, or the PC afferent.

IF mechanism 322 treats summation signal 342 as a postsynaptic current that drives the membrane potential in the soma. Membrane potential is also affected by a leak current with a time constant τₘ that drives it toward a resting potential Vr. Time constant τₘ will be further described with reference to FIG. 9 below.

FIG. 9 illustrates membrane time constants τₘ for the SA1, RA and PC afferents.

This figure includes examples of SA1 membrane time constant 902, RA membrane time constant 904 and PC membrane time constant 906. SA1 membrane time constant 902 includes time constant portion 908 and variability portion 910. RA membrane time constant 904 includes time constant portion 912 and variability portion 914. PC membrane time constant 1006 includes time constant portion 916 and variability portion 918.

Time constant portions 908, 912 and 916 may be membrane time constant value for the SA1, RA and PC mechanoreceptors. Variability portions 910, 914 and 918 may be acceptable error values associated with time constant portions 908, 912 and 916, respectively.

As illustrated in the figure, time constant portion 908 has a value of about 10 ms, time constant portion 912 has a value of about 9 ms and time constant portion 916 has a value of about 3 ms. The lower value of time constant portion 916 indicates the PC afferent has a faster time membrane time constant than SA1 and RA afferents.

Returning to FIG. 3, when the membrane potential reaches a voltage threshold VT (set to 1), a spike is registered and the membrane potential is reset to zero. To mimic the short refractory period following a spike, a post-spike inhibitory current is injected. The total post-spike inhibitory current at any given time is the sum of the post-spike currents due to all previous spikes.

The equations governing IF mechanism 322 are as follows:

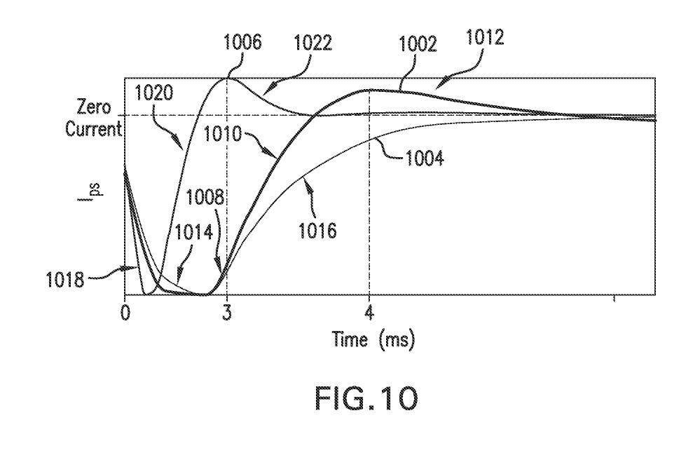

The membrane potential, V, is given by:

$$dV = ( - \frac{( V - {V}_{r} )}{{τ}_{m}} + {I}_{in} ( t ) + {I}_{ps} ( t ) ) dt + {W}_{t} \qquad ( 2 )$$

where Iₚₛ(t), the accumulated post-spike inhibitory current, is given by:

$${I}_{ps} ( t ) = {\sum }_{j = 0}^{s - 1} h ( t - {t}_{j} ) \qquad ( 3 )$$

where h is the waveform of a single post-spike inhibitory current, s is the number of past spikes, and tⱼ the time of the jth spike. Thus the post-spike current at time t represents the accumulation of the post-spike currents produced by all previous spikes. Iᵢₙ(t) is the input current, given by:

$${I}_{in} ( t ) = {\sum }_{i = 0}^{3} {H}_{i}^{+} ( t ) * {y}_{i}^{+} ( t ) + {H}_{i}^{-} ( t ) * {y}_{i}^{-} ( t ) \qquad ( 4 )$$

where yᵢ⁺(t) and yᵢ⁻(t) are the positive and negative components of the i^{th} derivative of position, respectively, and Hᵢ⁺(t) and Hᵢ⁻(t) are the corresponding linear filters, and the summation is performed for the variables hypothesized to drive the afferent response. In a non-limiting example embodiment, Hᵢ⁺(t) and Hᵢ⁻(t) may be the positive and negative components, respectively, of the band-pass filter 314, band-pass filter 316 and band-pass filter 318. Wₜ is Gaussian noise with zero mean and variance σ². The waveform of a single post-spike inhibitory current, h, will be further described with additional reference to FIG. 10 below.

FIG. 10 is a waveform of a single post-spike inhibitory current for the SA1, RA and PC afferents.

This figure includes examples of SA1 current 1002, RA current 1004 and PC current 1006.

SA1 current 1002 includes a portion 1008 from time 0 to time 2, a portion 1010 from time 2 to time 4, a portion 1012 from time 4 forward. RA current 1004 includes a portion 1014 from time 0 to time 2, a portion 1016 from time 2 forward. PC current 1006 includes a portion 1018 from time 0 to time 1, a portion 1020 from time 1 to time 3, a portion 1022 from time 3 forward.

In operation, SA1 current 1002 starts with a negative slope in portion 1008 and changes to a positive slope in portion 1010, then gradually decreases to zero current level in portion 1012.

RA current 1004 starts with a negative slope in portion 1014 and changes to a positive slope to gradually increase to zero current level in portion 1016.

PC current 1006 starts with a negative slope in portion 1018 and changes to a positive slope in portion 1020, then gradually decreases to zero current level in portion 1022. As the figure illustrated PC current 1006 approaches to zero current in a faster time course than SA1 current 1002 and RA current 1004.

As noted in FIGS. 2-10, transducer 108 transmits alternating electrical signal 206 based on an effect, such as pressure, of parameter 204, system 202 separates alternating electrical signal 206 into different aspects to generate signal 324, signal 326 and signal 328. System 202 applies a precise type of rectification to each aspect of parameter 204 to mimic rectification done by human sensory receptors.

Furthermore, system 202 applies filtering to each aspect of parameter 204 in a particular way to emulate filtering done by human sensory receptors. System 202 then applies summation for signal 324, signal 326 and signal 328 to generate summation signal 342.

Summation signal 342 is fed through IF mechanism 322 to generate processed electrical signal 208 that is equivalent to a neural signal generated by a natural limb affected by the same effect of parameter 204. Processor 110 receives processed electrical signal 208 from system 202 and transmits a neural signal based on processed electrical signal 208 to the nervous system of a wearer of a prosthetic arm via neural transmitter port 112, thus recreating real sensation through the prosthesis.

The foregoing description of various preferred embodiments of the invention have been presented for purposes of illustration and description. It is not intended to be exhaustive or to limit the invention to the precise forms disclosed, and obviously many modifications and variations are possible in light of the above teaching. The example embodiments, as described above, were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A system for use with a transducer and a neural transmitter port, the transducer being operable to be affected by a parameter and to provide an alternating electrical signal based on an effect of the parameter, the neural transmitter port being operable to receive a processed electrical signal and output the processed electrical signal to a neural transmitter, said system comprising:
an input portion operable to output a first signal based on the alternating electrical signal;
a band-pass filter operable to output a first filtered signal based on the first signal; and
an integrate-and-fire mechanism operable to generate the processed electrical signal based on the first filtered signal.

2. The system of claim 1, further comprising:
a rectifying portion operable to generate a rectified signal based on the first signal,
wherein said band-pass filter is operable to output the first filtered signal based on the rectified signal.

3. The system of claim 2, wherein said rectifying portion is operable to generate the rectified signal additionally based on a rectification index less than or equal to 1.

4. The system of claim 3, further comprising:
a second input portion operable to output a second signal based on the alternating electrical signal; and
a second band-pass filter operable to output a second filtered signal based on the second signal,
wherein said integrate-and-fire mechanism is operable to generate the processed electrical signal based on the first filtered signal and the second filtered signal.

5. The system of claim 4, wherein said second input portion is operable to output the second signal as a derivative of the first signal.

6. The system of claim 5, further comprising a summing portion operable to output a summation signal based on a sum of the first filtered signal and the second filtered signal.

7. The system of claim 6, further comprising:
a second rectifying portion operable to generate a second rectified signal based on the second signal,
wherein said second band-bass filter is operable to output the second filtered signal based on the second rectified signal.

8. The system of claim 7, wherein said second rectifying portion is operable to generate the second rectified signal additionally based on a second rectification index less than or equal to 1.

9. A method of using a transducer and a neural transmitter port, the transducer being operable to be affected by a parameter and to provide an alternating electrical signal based on an effect of the parameter, the neural transmitter port being operable to receive a processed electrical signal and output the processed electrical signal to the neural transmitter, said method comprising:
outputting, via an input portion, a first signal based on the alternating electrical signal;
outputting, via a band-pass filter, a first filtered signal based on the first signal; and
generating, via an integrate-and-fire mechanism, the processed electrical signal based on the first filtered signal.

10. The method of claim 9, further comprising:
generating, via a rectifying portion, a rectified signal based on the first signal,
wherein said outputting, via a band-pass filter, a first filtered signal based on the first signal comprises outputting, via the band-bass filter, the first filtered signal based on the rectified signal.

11. The method of claim 10, wherein said generating, via a rectifying portion, a rectified signal based on the first signal comprises generating, via the rectifying portion, the rectified signal additionally based on a rectification index less than 1.

12. The method of claim 11, further comprising:
outputting, via a second input portion, a second signal based on the alternating electrical signal; and
outputting, via a second band-pass filter, a second filtered signal based on the second signal,
wherein said generating, via an integrate-and-fire mechanism, the processed electrical signal based on the first filtered signal comprises generating, via the integrate-and-fire mechanism, the processed electrical signal based on the first filtered signal and the second filtered signal.

13. The method of claim 12, wherein said outputting, via a second input portion, a second signal based on the alternating electrical signal comprises outputting, via the second input portion, the second signal as a derivative of the first signal.

14. The method of claim 13, further comprising outputting, via a summing portion, a summation signal based on a sum of the first filtered signal and the second filtered signal.

15. The method of claim 14, further comprising:
generating, via a second rectifying portion, a second rectified signal based on the second signal,
wherein said outputting, via a second band-pass filter, a second filtered signal based on the second signal comprises outputting, via the second band-bass filter, the second filtered signal based on the second rectified signal.

16. The method of claim 15, wherein said generating, via a second rectifying portion, a second rectified signal based on the second signal comprises generating, via the second rectifying portion, the second rectified signal additionally based on a second rectification index less than 1.
